(19) United States
(12) Patent Application Publication
(10) Pub. No.: US 2025/0006825 A1
(43) Pub. Date: Jan. 2, 2025

(54) RC IGBT and Method of Operating a Half Bridge Circuit

(71) Applicant: Infineon Technologies AG, Neubiberg (DE)

(72) Inventor: Hans-Guenter Eckel, Rostock (DE)

(21) Appl. No.: 18/754,542

(22) Filed: Jun. 26, 2024

(30) Foreign Application Priority Data
Jun. 27, 2023 (DE) 102023116868.1

(51) Int. Cl. H01L 29/739; H01L 27/07; H01L 29/06; H01L 29/10; H01L 29/66

(52) U.S. Cl. CPC H01L 29/7397; H01L 27/0727; H01L 29/0696; H01L 29/1095; H01L 29/6609

(57) ABSTRACT

An RC IGBT includes, in a single chip, an active region configured to conduct both a forward load current and a reverse load current between a first load terminal at a front side of a semiconductor body of the RC IGBT and a second load terminal at a back side of the semiconductor body. The active region is separated into at least an IGBT-only region and an RC IGBT region. At least 90% of the IGBT-only region is configured to conduct, based on a first control signal, only the forward load current. At least 90% of the RC IGBT region is configured to conduct the reverse load current and, based on a second control signal, the forward load current.

### TECHNICAL FIELD

This specification refers to embodiments of an RC IGBT and to embodiments of operating a half bridge circuit.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a forward load current along a load current path between two load terminals of the device. The load current is typically conducted by means of an active region of the power semiconductor device. The active region is typically surrounded by an edge termination region, which is terminated by an edge of the chip.

In case of a controllable power semiconductor device, e.g., a transistor, the load current path may be controlled by means of an insulated electrode, commonly referred to as gate electrode. For example, upon receiving a corresponding control signal, e.g., from a driver unit via a control terminal of the device, the control electrode may set the power semiconductor device in one of a forward conducting state and a blocking state.

Furthermore, some devices provide for reverse load current capability; i.e., the active region of the semiconductor body is further configured to conduct a reverse load current along a reverse load current path between the two load terminals of the device. For example, the RC (Reverse Current) IGBT is one representative of such devices. In an RC IGBT, a single chip unites an IGBT structure and a diode structure, wherein not only the IGBT may be controlled based on said gate signal, but wherein also the characteristic of the diode behavior may be influenced. In comparison to a separate diode and a separate IGBT connected anti-parallel to each other, the RC IGBT exhibits some advantages, e.g., in terms on-state losses and/or thermal behavior, but may also be more complex in control.

### SUMMARY

The subject-matter of the independent claims is presented. Features of exemplary embodiments are defined in the dependent claims.

According to an embodiment, an RC IGBT comprises, in a single chip, an active region configured to conduct both a forward load current and a reverse load current between a first load terminal at a front side of a semiconductor body of the RC IGBT and a second load terminal at a back side of the semiconductor body. The active region is separated into at least an IGBT-only region, at least 90% of which being configured to conduct, based on a first control signal, only the forward load current; and an RC IGBT region, at least 90% of which being configured to conduct the reverse load current and, based on a second control signal, the forward load current.

According to a further embodiment, a method of operating a half bridge circuit is presented. The half bridge circuit comprises a first RC IGBT according to the above embodiment and a second RC IGBT according to the above embodiment. The method comprises: controlling the first RC IGBT based on the first control signal and the second control signal of the first RC IGBT; and controlling the second RC IGBT based on the first control signal and the second control signal of the second RC IGBT.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a section of a horizontal projection of an RC IGBT in accordance with one or more embodiments;

FIG. 2 schematically and exemplarily illustrates a section of a horizontal projection of an active region of an RC IGBT in accordance with one or more embodiments;

FIGS. 3-5 each schematically and exemplarily illustrate a section of a vertical cross-section of an RC IGBT in accordance with one or more embodiments; and

FIG. 6 schematically and exemplarily illustrates a method of operating a half bridge circuit in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, an RC IGBT, e.g., a power semiconductor device that may be used within a power converter or a power supply. Thus, in an embodiment, such RC IGBT can be configured to carry a load current that is to be fed to a load and/or, respectively, that is provided by a power source. For example, the RC IGBT may comprise one or more active power semiconductor unit cells, such as a monolithically integrated diode cell, a derivative of a monolithically integrated diode cell, a monolithically integrated transistor cell, e.g., a monolithically integrated IGBT cell and/or derivatives thereof. Such diode/transistor cells may be integrated in a power semiconductor module. A plurality of such cells may constitute a cell field that is arranged within an active region of the power semiconductor device.

The term “blocking state” of the RC IGBT may refer to conditions, when the RC IGBT is in a state configured for blocking a load current flow while an external voltage is applied. More particularly, the RC IGBT may be configured for blocking a forward load current through the RC IGBT while a forward voltage bias is applied. In comparison, the RC IGBT may be configured for conducting the forward load current in a “conducting state” of the RC IGBT while a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the RC IGBT. The term “forward biased blocking state” therefore may refer to conditions with the RC IGBT being in the blocking state while a forward voltage bias is applied.

The term “RC IGBT” as used in this specification intends to describe an RC IGBT on a single chip with high voltage blocking and/or high current-carrying capabilities. In other words, such RC IGBT is intended for high current, typically in the Ampere range, e.g., up to several ten or hundred Ampere, and/or high voltages, typically 100 V and above, e.g., at least 400 V or even more, e.g., at least 3 kV, or even up to 10 kV or more, depending on the respective application.

For example, the term “RC IGBT” as used in this specification is not directed to logic semiconductor devices that are used for, e.g., storing data, computing data and/or other types of semiconductor based data processing.

For example, the RC IGBT described below may be a single semiconductor chip, e.g., exhibiting a stripe cell configuration (or a cellular/needle cell configuration) and can be configured to be employed as a power component in a low-, medium- and/or high voltage application.

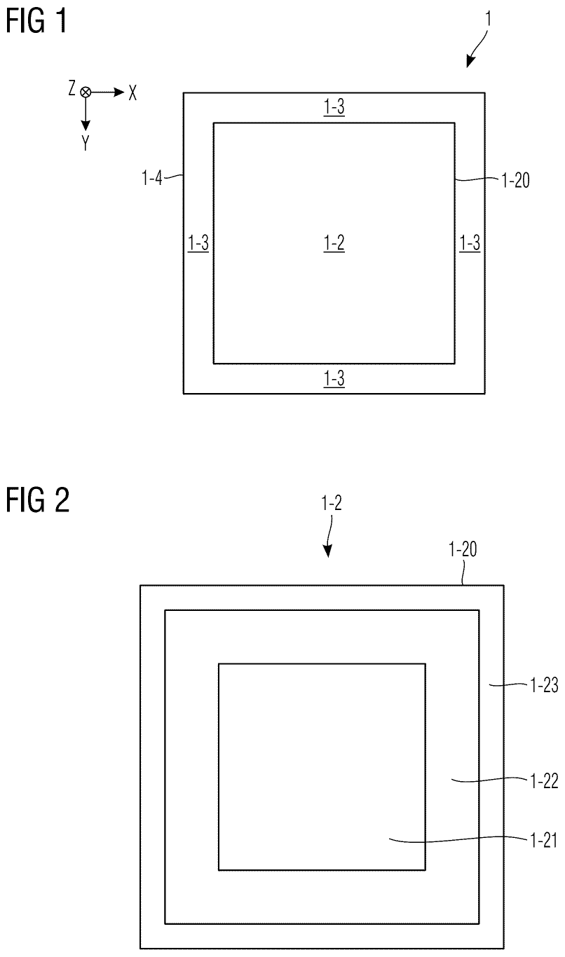

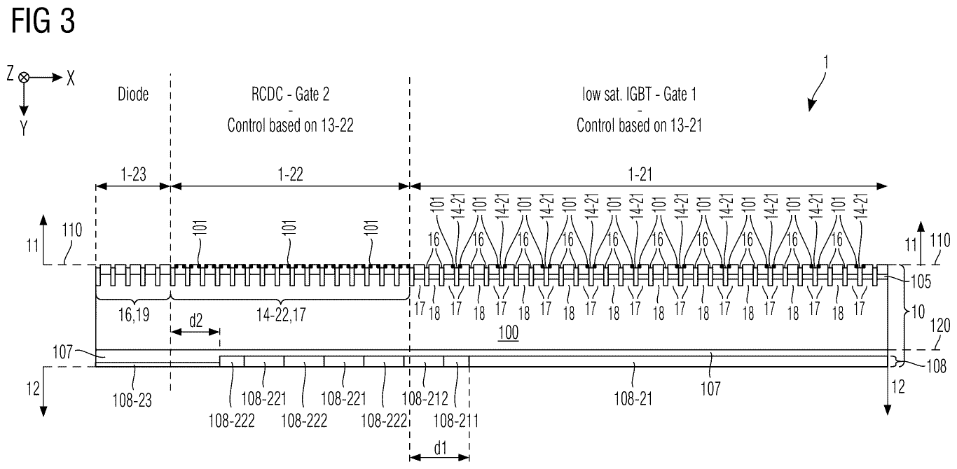

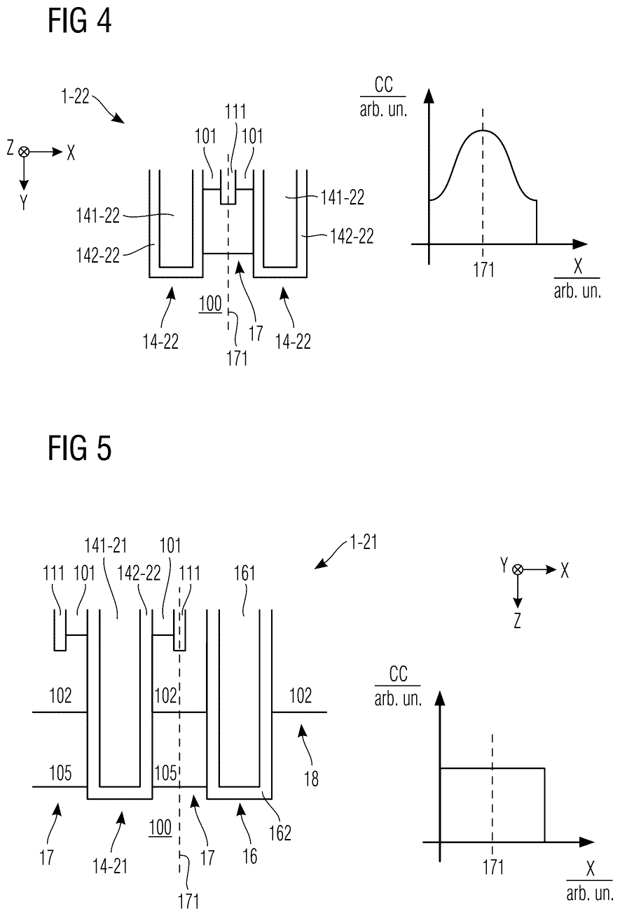

FIG. 1 schematically and exemplarily illustrates a section of a horizontal projection of a RC IGBT 1 in accordance with one or more embodiments. The vertical cross-sections illustrated in FIGS. 3 to 5 as well as the more detailed illustration of an exemplary active region 1-2 according to FIG. 2 are additionally referred to in the following.

Accordingly, the RC IGBT 1 comprises a semiconductor body 10 coupled to a first load terminal at a front side (also referred to as first side) 110 and to a second load terminal 12 at a back side (also referred to as back side) 120 that is opposite to the front side 110 with respect to the vertical direction Z. The semiconductor body 10 is part of a single chip that comprises an active region 1-2 configured to conduct both a forward load current and a reverse load current between the first load terminal 11 and the second load terminal 12 at the back side 120.

The RC IGBT 1 may thus exhibit a vertical configuration according to which the both the forward load current and the reverse load current flow substantially in parallel to the vertical direction Z.

For example, the first load terminal 11 may be a source (or emitter) terminal, and the second load terminal 12 a drain (collector) terminal.

The active region 1-2 is surrounded by an edge termination region 1-3 which is terminated by a chip edge 1-4. Herein, the terms “active region” (sometimes also referred to as “cell field”), “edge termination region” and “chip edge” have the technical meanings the skilled person typically associates therewith in the context of RC IGBTs and are hence not explained in further detail.

According to the embodiments disclosed herein, the active region 1-2 of the RC IGBT 1 is separated into at least an IGBT-only region 1-21 and an RC IGBT region 1-22. At least 90% of the IGBT-only region 1-21 is configured to conduct, based on a first control signal 13-21, only the forward load current. At least 90% of the RC IGBT region 1-22 is configured to conduct the reverse load current and, based on a second control signal 13-22, the forward load current.

In addition, the active region 1-2 may comprise a diode-only region 1-23, which will be explained in more detail below.

It shall be understood that the arrangement of the IGBT-only region 1-21, the RC IGBT region 1-22 and the optional diode-only region 1-23 as illustrated in FIG. 2 is only exemplary. For example, said three regions 1-21, 1-22 and 1-23 must not necessarily be contiguous regions but could also be constituted by spatially distributed subregions. Also, instead of being centrally arranged, the IGBT-only region 1-21 could alternatively or additionally be arranged in periphery portions of the active region 1-2. The skilled person may dimension and arrange said three regions 1-21, 1-22 and 1-23 within the active region 1-2 according to the designated characteristics of the RC IGBT 1.

In an embodiment, the second control signal 13-22 is different from the first control signal 13-21. For example, the second control signal 13-22 is determined/generated separately from the first control signal 13-21. Thereby, the control of the IGBT-only region 1-21 can be independent of the control of the RC IGBT region 1-22. That is, in an embodiment, instead of providing only an RC IGBT region in the active region, the active region is separate into at least a) the distinct IGBT-only region 1-21 that only carries the forward load current (and not the reverse load current) and that is controlled based on the first control signal 13-21 and b) the distinct RC IGBT region 1-22 that carries both the forward load current and the reverse load current and that is controlled based on the second control signal 13-22 that may be independent of the first control signal 13-21.

In an embodiment, the RC IGBT region 1-22 is configured to conduct the reverse load current irrespective of the second control signal 13-22.

The IGBT-only region 1-21 and the RC IGBT region 1-22 may occupy the major portion of the active region 1-2; e.g., the IGBT-only region 1-21 and the RC IGBT region 1-22 amount to at least 80% of the active region 1-2. A remaining portion of the active region 1-2 may, for example, be occupied by the optional diode-only region 1-23.

In an embodiment, wherein the IGBT-only region 1-21 is spatially separated from the RC IGBT region 1-22. For example, there is no spatial overlap between the IGBT-only region 1-21 and the RC IGBT region 1-22.

Further, the IGBT-only region 1-21 can be a first contiguous region, and the RC IGBT region 1-22 can a second contiguous region that is, e.g., separately arranged from the first contiguous region.

For example, at least 90% of the optional diode-only region 1-23 is configured to conduct only the reverse load current (but, e.g., not the forward load current). In an embodiment, the diode-only region 1-23 is not subjected to the first control signal 13-21 or the second control signal 13-22.

As indicated above, the skilled person may dimension and arrange said three regions 1-21, 1-22 and 1-23 within the active region 1-2 according to the designated characteristics of the RC IGBT 1. Furthermore, the formulation “at least 90%” used within the context of describing these regions shall express that the primary purpose of the regions is conduct either the forward load current only (in case of the IGBT-only region 1-21), or the reverse load current only (in case of the optional diode-only region 1-23) or both the forward load current and the reverse load current (in case of the RC IGBT region 1-22). Of course, the characteristics may deviate in smaller subportions of said regions, e.g., in a transition region where the IGBT-only region 1-21 adjoins the RC IGBT region 1-22. Such transitions will be described further below in more detail.

Reference will now be made in more detail to FIG. 3, which illustrates a section of a vertical cross-section of an exemplary embodiment of the active region 1-2, which includes the IGBT-only region 1-21, the RC IGBT region 1-22 and the diode-only region 1-23. It is again emphasized that the diode-only region 1-23 is optional. In other embodiments, the reverse load current is entirely carried by the RC IGBT region 1-22, such that the distinct diode-only region 1-23 can be omitted.

As illustrated, the active region 1-2 exhibits a vertical configuration with the first load terminal 11 being arranged at the semiconductor body front side 110 and the second load terminal 12 being arranged at the semiconductor body back side 120. The first load terminal 11 and the second load terminal 12 may be shared by each of the IGBT-only region 1-21, the RC IGBT region 1-22 and the diode-only region 1-23.

A drift region 100 of the first conductivity type may form the mayor central portion of the semiconductor body 10 with respect to the vertical direction Z. This drift region 100 may be shared by each of the IGBT-only region 1-21, the RC IGBT region 1-22 and, if implemented, by the diode-only region 1-23.

The active region 1-2 may be configured, both at the front side 110 and at the back side 120 according to the distribution of the IGBT-only region 1-21, the RC IGBT region 1-22 and the diode-only region 1-23.

For example, regarding the back side 120, in electrical connection with the second load terminal 12, there is a arranged a back side emitter 108 coupled to the drift region 100, wherein the back side emitter 108 is configured in accordance with the separation of the active region 1-2 into at least the IGBT-only region 1-21 and the RC IGBT region 1-22 and, if implemented, the diode-only region 1-23.

In an embodiment, the back side emitter 108 may be configured with:
a first section 108-21 of the second conductivity type in a portion of the active region 1-2 where the IGBT-only region 1-21 is present;
a second section 108-22 including both first subsections 108-221 of the first conductivity type and second subsections 108-222 of the second conductivity type in a portion of the active region 1-2 where the RC IGBT region 1-22 is present;
and, optionally, if the diode-only region 1-23 is implemented, with a third section 108-23 of the first conductivity type in a portion of the active region 1-2 where the diode-only region 1-23 is present.

For example, the first section 108-21 of the back side emitter 108 exhibits, with respect to its total lateral extension along the first lateral direction X and at a certain vertical level, an average dopant concentration of at least 1*10¹³ cm⁻³ or even at least 1*10¹⁴ cm⁻³. Further, the first section 108-21 can be displaced from the RC IGBT region 1-22 by a first distance d1 of at least 20% of the thickness of the drift region 100 along the vertical direction Z.

In an embodiment, each of the first subsections 108-221 of the second section 108-22 of the back side emitter 108 exhibits, with respect to its respective total lateral extension along the first lateral direction X and at a certain vertical level, an average dopant concentration of at least 1*10¹³ cm⁻³ or even at least 1*10¹⁴ cm⁻³. Further, each of the first subsections 108-221 can be displaced from the diode-only region 1-23 by a second distance d2 of at least 20% of the thickness of the drift region 100 along the vertical direction Z.

In a further embodiment, the RC IGBT 1 further comprises a field stop region 107 of the first conductivity type arranged in contact with both the drift region 100 and with each of the first section 108-21, the second section 108-22 and, if implemented, the third section 108-23 of the back side emitter 108. The dopant concentration of the field stop region 107 can be greater than the dopant concentration of the drift region 100.

As indicated above, the configuration of the active region 1-2 may also at the front side 110 reflect the active region's 1-2 separation into the at least the IGBT-only region 1-21 and the RC IGBT region 1-22 and, if implemented, the diode-only region 1-23. For example, the RC IGBT 1 further comprises, between the first load terminal 11 and the drift region 100, a trench-mesa-pattern, wherein the trench-mesa-pattern is configured in accordance with the separation of the active region 1-2 into at least the IGBT-only region 1-21 and the RC IGBT region 1-22 and, if implemented, the diode-only region 1-23.

An exemplary configuration of the front side trench mesa pattern is illustrated in FIG. 3. For example, the trench-mesa-pattern is configured with:
first control trenches 14-21 arranged in the IGBT-only region 1-21 and configured to receive the first control signal 13-21; and with
second control trenches 14-22 arranged in the RC IGBT region 1-22 and configured to receive the second control signal 13-22.

In an embodiment, the RC IGBT region 1-22 does not comprise any first control trench 14-21. Further, it may be provided that the IGBT-only region 1-21 does not comprise any second control trench 14-22.

In an embodiment, the trench-mesa-pattern may further be configured with source trenches 16 electrically connected to the first load terminal 11 and arranged at least in the IGBT-only region 1-21 and, if implemented, optionally also in the diode-only region 1-23. For example, the RC IGBT region 1-22 does not comprise any source trench 16.

In an embodiment, the trench-mesa-pattern may further be configured with first type mesas 17 arranged in both the IGBT-only region 1-21 and the RC IGBT region 1-23, wherein each first type mesa 17 includes a source region 101 of the first conductivity type and a body region 102 of the second conductivity type. For the sake of a clear representation, only a few of the source regions 101 present in the RC IGBT region 1-22 are provided with a reference sign. Each bold little square represents a source region. Furthermore, each illustrated trench in the RC IGBT region 1-22 represents a second control trench 14-22, wherein the second control trenches 14-22 laterally confine the first type mesas 17 in the RC IGBT region 1-22.

Regarding both the RC IGBT region 1-22 and the IGBT-only region 1-21, both the source region 101 and the body region 102 are electrically connected to the first load terminal 11. At least the body region 102 isolates the source region 101 from the drift region 100.

In an example, in the IGBT-only region 1-21, each first type mesa 17 is arranged adjacent at least one of the first control trenches 14-21. Each first control trench 14-21 is configured to induce, in response to receiving a corresponding configuration of the first control signal 13-21, a conductive channel in the adjacent first type mesa 17 for conduction of the forward load current. Correspondingly, in the RC IGBT region 1-22, each first type mesa 17 may be arranged adjacent at least one of the second control trenches 14-22. Each second control trench 14-22 is configured to induce, in response to receiving a corresponding configuration of the second control signal 13-22, a conductive channel in the adjacent first type mesa 17 for conduction of the forward load current.

As explained above, the above described trench-mesa-pattern is only one of many possible examples. For example, at least in the IGBT-only region 1-21, the trench-mesa-pattern may further comprise second type mesas 18 that are not equipped with a source region 101 and that may or may not be electrically connected to the first load terminal 11. Further, additional trench types, such as floating trenches (whose trench electrodes are not electrically connected to a defined potential) or further control trenches may be provided.

For example, in the optionally provided diode-only region 1-23, only source trenches 16 but no control trenches are provided. These source trenches 16 may laterally confine diode mesas 19, wherein the body region 102 is electrically connected to the first load terminal 11.

Here, it shall be understood that the configurations of the front side 110 and the back side 120, i.e., the trench-mesa-pattern at the front side 110 and the back side emitter 108 at the back side 120 are aligned with each other according to the separation of the active region 1-2 into the RC IGBT region 1-22, the IGBT-only region 1-21 and the optional diode-only region 1-23. That is, the above explained trench-mesa-configuration in diode-only region 1-23 laterally overlaps with the above explained configuration of the back side emitter 108 in the diode-only region 1-23, and the above explained trench-mesa-configuration in IGBT-only region 1-21 laterally overlaps with the above explained configuration of the back side emitter 108 in the IGBT-only region 1-21, and the above explained trench-mesa-configuration in RC IGBT region 1-22 laterally overlaps with the above explained configuration of the back side emitter 108 in the RC IGBT region 1-22, according to an embodiment.

In an embodiment, in the RC IGBT region 1-22, the body regions 102 in the first type mesas 17 exhibit a respective lateral dopant profile according to which the dopant concentration peaks in a lateral center region 171 of the respective first type mesa 17. This optional aspect is illustrated in FIG. 4, which also exemplarily illustrates a more detailed configuration of the second control trenches 14-22. Each second control trench 14-22 may exhibit a second control trench electrode 141-22 that is electrically insulated from the semiconductor body 10 by a second control trench insulator 142-22. As explained above, two of such second control trenches 14-22 laterally confine a first type mesa 17 that is equipped with one or more of the source regions 101 and the body region 102 that may isolate the source region(s) 101 from the drift region 100 (or an optionally implemented barrier region 105, as explained below). Both the source region(s) 101 and the body region 102 are electrically connected to the first load terminal 11, e.g., based on a contact plug 111, as illustrated in FIG. 4. In the RC IGBT region 1-22, the dopant concentration of the body region 102 may peak in the lateral center region 171 of the respective first type mesa 17, as schematically illustrated in the graph right to the section of the trench-mesa-pattern in FIG. 4.

By contrast, the dopant concentration of the body region 102 in the IGBT-only region 1-21 may be constant. This optional aspect is illustrated in FIG. 5, which also exemplarily illustrates a more detailed configuration of the trench-mesa-pattern in the IGBT-only region 1-21. As the second control trenches 14-22, each first control trench 14-21 may exhibit a first control trench electrode 141-21 that is electrically insulated from the semiconductor body 10 by a first control trench insulator 142-21. Analogously, each source trench 16 may exhibit a source trench electrode 161 that is electrically insulated from the semiconductor body 10 by a source trench insulator 162. For example, on each side of the first control trench 14-21, there is arranged a respective one of the first type mesas 17, which is, on its other side, laterally confined by a respective one of the source trenches 16. In this example, the first type mesa 17 are only equipped with one source region 101, arranged adjacent to the trench sidewalls of the first control trench 14. No source regions 101 are arranged adjacent to the trench sidewalls of the source trench 16. In the IGBT-only region 1-21, the dopant concentration of the body region 102 may be substantially constant along the first lateral direction X in the respective first type mesa 17, as schematically illustrated in the graph right to the section of the trench-mesa-pattern in FIG. 5.

In an embodiment, the RC IGBT 1 further comprises a barrier region 105 of the first conductivity type that couples the trench-mesa-pattern in the IGBT-only region 1-21 to the drift region 100, wherein the dopant concentration of the barrier region 105 is greater than the dopant concentration of the drift region 100. As illustrated in FIGS. 3, 4 and 5, the barrier region 105 is for example only provided in the IGBT-only region 1-21 and neither provided in the RC IGBT region 1-22 nor in the diode-only region 1-23.

In more general terms, a first channel-width-to-area-ratio can be defined by a total channel width in the IGBT-only region 1-21 divided by a total lateral area of IGBT-only region 1-21, and a second channel-width-to-area-ratio can be defined by a total channel width in the RC IGBT region 1-22 divided by a total lateral area of RC IGBT region 1-22. In an embodiment, the second channel-width-to-area-ratio amounts to at least 120% of the first channel-width-to-area-ratio.

Based on the above-described exemplary design, the IGBT-only region 1-21 may constitute a low saturation IGBT that is controlled based on the first control signal 13-21 (Gate 1), and the RC IGBT region 1-22 may constitute RCDC IGBT region with reverse conductivity (RC) and diode control (DC) characteristic that is controlled based on the second control signal 13-22 (Gate 2).

In an embodiment, the RC IGBT region 1-22 occupies a total of 20% to 30% of the active region 1-2, and the IGBT-only region 1-21 occupies a total of 65% to 75% of the active region 1-2, and the diode-only region 1-23 occupies a total of 0% to 15% of the active region 1-2. Or, the RC IGBT region 1-22 occupies a volume amounting to at least . . . % of the volume occupied by the IGBT-only region 1-21.

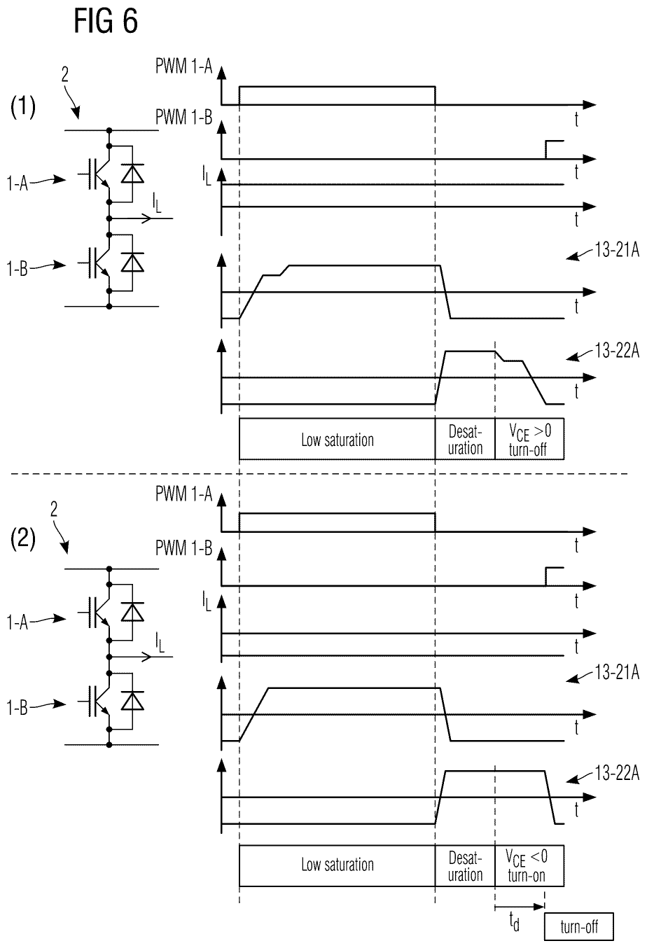

Presented herein is also a method of operating a half bridge circuit 2 comprising a first RC IGBT 1-A according to one of the preceding embodiments and a second RC IGBT 1-B according to one of the preceding embodiments. An exemplary method will be explained with respect to FIG. 6.

The RC IGBTs 1-A and 1-B may be equally configured.

Generally, the method comprises controlling the first RC IGBT 1-A based on the first control signal 13-21A and the second control signal 13-22A of the first RC IGBT 1-A, and controlling the second RC IGBT 1-B based on the first control signal 13-21B and the second control signal 13-22B of the second RC IGBT 1-B.

To better understand the exemplary control method, the tables below exemplarily summarize the states and corresponding control signals for the RC IGBT 1-A (and, correspondingly, for the second RC IGBT 1-B:

TABLE 1

| IGBT-only region | | First control |
|---|---|---|
| 1-21 // First | First control voltage | voltage |
| control signal 13-21 | between −15 V and 0 V | equals 15 V |
| IGBT mode | Blocking | Conductive at |
| | | low V_{CE} |
| Diode mode | Blocking | Blocking |

TABLE 2

| RC IGBT region | | |
|---|---|---|
| 1-22 // Second | Second control voltage | Second control |
| control signal 13-22 | between −15 V and 0 V | voltage equals 15 V |
| IGBT mode | Blocking | Conductive, low charge |
| Diode mode | Conducting, low V_{F} | Conductive, unipolar, |
| | | low/no charge |

TABLE 3

| Diode-only region 1-23 // | |
|---|---|
| No control signal | |
| IGBT mode | Blocking |
| Diode mode | Conductive, low charge |

For example, considered in isolation, the IGBT-only region 1-21 hence behaves like a regular IGBT, the RC IGBT region 1-22 behaves like a regular RC IGBT and the diode-only region 1-23 behaves like a regular diode. With the states summarized in tables 1 to 3, the RC IGBT 1 (1-A/1-B) may be set into the following states.

TABLE 4

| | | IGBT Mode | Diode Mode |
|---|---|---|---|
| State 1 | First Control voltage = +15 V | Low V_{CE} in IGBT-only | Low V_{F} in RC IGBT |
| Conduction | Second control voltage between −15 V and 0 V | region 1-21 | region 1-22 |
| State 2 | First Control voltage between −15 V and 0 V | Low charge in RC IGBT | Low charge in diode-only |
| Desaturation and diode | Second control voltage = +15 V | region 1-22 | region 1-23 |
| mode locking time | | | |
| State 3 | First Control voltage between −15 V and 0 V | Turn-off in RC IGBT | Low V_{F} in RC IGBT |
| Locking time IGBT mode | Second control voltage value corresponding to | region 1-22 | region 1-22. |
| | discharge | | |

With these states in mind, it becomes apparent that a desaturation is possible both in the diode mode and in the IGBT mode of the RC IGBT 1, as exemplarily illustrated for the first RC IGBT 1-A in FIG. 6.

In an embodiment, the four control signals 13-21A, 13-22A, 13-21B and 13-22B are derived from a PWM signal for the first RC IGBT 1-A (PWM 1-A) and from a PWM signal for the second RC IGBT 1-B (PWM 1-B). In FIG. 6, these signals PWM 1-A and PWM 1-B are illustrated for two scenarios: (1) The half bridge load current I_{L} is positive (cf. upper part of FIG. 6) and (2) the half bridge load current I_{L} is negative (cf. lower half of FIG. 6).

The upper portion of FIG. 6 (I_{L}>0) illustrates the situation for the first RC IGBT 1-A being in the IGBT mode, and lower portion of FIG. 6 (I_{L}>0) illustrates the situation for the first RC IGBT 1-A being in the diode mode.

An exemplary embodiment will now be explained:

As soon as the PWM signal PWM 1-A is switched to “high” (or “on”), the control signal 13-21A is set to +15V and the control signal 13-22A stays at (−15V . . . 0V). This ensures low saturation conduction in the IGBT-mode as well as in the diode-mode (see table 4). As the PWM signal PWM 1-A is switched to “low” (or “off”), the control signal 13-22A is set to +15V. With a small overlap the control signal 13-21A is set to (−15V . . . 0V). This ensures desaturation in the IGBT-mode as well as in the diode mode. After a predefined desaturation time (of, e.g., 2 μs to 200 μs), the further behavior depends on the current direction of I_{L}. In case of transistor mode, I_{L}>0 (which can, e.g., be detected by a positive collector-emitter voltage), the IGBT is turned off by setting the control signal 13-22A to (−15V . . . 0V). In case of diode mode, I_{L}<0 (which can, e.g., be detected by a negative collector-emitter voltage), the diode is being kept in the desaturation mode by keeping control signal 13-22A to +15V. In this case, 13-22A is set to (−15V . . . 0V) only immediately before the opposite IGBT is turned on.

In the above, embodiments pertaining to RC IGBTs, and corresponding operating methods were explained. For example, these RC IGBTs are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

As used herein, the terms “having”, “containing”, “including”, “comprising”, “exhibiting” and the like are open ended terms that indicate the presence of stated elements or features, but do not preclude additional elements or features.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. An RC IGBT, comprising:
in a single chip, an active region configured to conduct both a forward load current and a reverse load current between a first load terminal at a front side of a semiconductor body of the RC IGBT and a second load terminal at a back side of the semiconductor body,
wherein the active region is separated into at least an IGBT-only region and an RC IGBT region,
wherein at least 90% of the IGBT-only region is configured to conduct, based on a first control signal, only the forward load current,
wherein at least 90% of the RC IGBT region is configured to conduct the reverse load current and, based on a second control signal, the forward load current.

2. The RC IGBT of claim 1, wherein the second control signal is different from the first control signal.

3. The RC IGBT of claim 1, wherein the IGBT-only region and the RC IGBT region amount to at least 80% of the active region.

4. The RC IGBT of claim 1, wherein the IGBT-only region is spatially separated from the RC IGBT region.

5. The RC IGBT of claim 4, wherein the IGBT-only region is a first contiguous region and/or the RC IGBT region is a second contiguous region.

6. The RC IGBT of claim 1, further comprising:
a diode-only region,
wherein at least 90% of the diode-only region is configured to conduct only the reverse load current.

7. The RC IGBT of claim 1, further comprising:
a drift region of a first conductivity type in the semiconductor body,
wherein the drift region is shared by the IGBT-only region and the RC IGBT region.

8. The RC IGBT of claim 7, further comprising:
a back side emitter in electrical connection with the second load terminal and coupled to the drift region,
wherein the back side emitter is configured in accordance with the separation of the active region into at least the IGBT-only region and the RC IGBT region.

9. The RC IGBT of claim 8, wherein the back side emitter comprises:
a first section of a second conductivity type in a portion of the active region where the IGBT-only region is present; and
a second section including both first subsections of a first conductivity type and second subsections of the second conductivity type in a portion of the active region where the RC IGBT region is present.

10. The RC IGBT of claim 9, wherein the first section of the back side emitter exhibits, with respect to a total lateral extension of the first section along a first lateral direction and at a certain vertical level, an average dopant concentration of at least 1*10¹³ cm⁻³, wherein the first section is displaced from the RC IGBT region by a first distance of at least 20% of a thickness of a drift region of the first conductivity type in the semiconductor body, and wherein the drift region is shared by the IGBT-only region and the RC IGBT region.

11. The RC IGBT of claim 9, further comprising:
a diode-only region,
wherein at least 90% of the diode-only region is configured to conduct only the reverse load current,
wherein each of the first subsections of the second section of the back side emitter exhibits, with respect to a respective total lateral extension of each first subsection along a first lateral direction and at a certain vertical level, an average dopant concentration of at least 1*10¹³ cm⁻³, wherein each of the first subsections is displaced from the diode-only region by a second distance of at least 20% of a thickness of a drift region of the first conductivity type in the semiconductor body, and wherein the drift region is shared by the IGBT-only region and the RC IGBT region.

12. The RC IGBT of claim 9, further comprising:
a drift region of a first conductivity type in the semiconductor body; and
a field stop region of the first conductivity type arranged in contact with the drift region of the first conductivity type and with both of the first section and the second section of the back side emitter,
wherein the drift region is shared by the IGBT-only region and the RC IGBT region,
wherein a dopant concentration of the field stop region is greater than a dopant concentration of the drift region.

13. The RC IGBT of claim 1, further comprising:
a drift region of a first conductivity type in the semiconductor body; and
a trench-mesa-pattern between the first load terminal and the drift region,
wherein the drift region is shared by the IGBT-only region and the RC IGBT region,
wherein the trench-mesa-pattern is configured in accordance with the separation of the active region into at least the IGBT-only region and the RC IGBT region.

14. The RC IGBT of claim 13, wherein the trench-mesa-pattern comprises:
first control trenches arranged in the IGBT-only region and configured to receive the first control signal; and
second control trenches arranged in the RC IGBT region and configured to receive the second control signal.

15. The RC IGBT of claim 13, wherein the trench-mesa-pattern comprises:
source trenches electrically connected to the first load terminal and arranged at least in the IGBT-only region.

16. The RC IGBT of claim 13, wherein the trench-mesa-pattern comprises:
first type mesas arranged in both the IGBT-only region and the RC IGBT region,
wherein each first type mesa includes a source region of the first conductivity type and a body region of a second conductivity type,
wherein both the source region and the body region are electrically connected to the first load terminal, and
wherein at least the body region isolates the source region from the drift region.

17. The RC IGBT of claim 16, wherein the trench-mesa-pattern comprises:
first control trenches arranged in the IGBT-only region and configured to receive the first control signal; and
second control trenches arranged in the RC IGBT region and configured to receive the second control signal,
wherein in the IGBT-only region, each first type mesa is arranged adjacent at least one of the first control trenches, and each first control trench is configured to induce, in response to receiving a corresponding configuration of the first control signal, a conductive channel in the adjacent first type mesa for conduction of the forward load current, and
wherein in the RC IGBT region, each first type mesa is arranged adjacent at least one of the second control trenches, and each second control trench is configured to induce, in response to receiving a corresponding configuration of the second control signal, a conductive channel in the adjacent first type mesa for conduction of the forward load current.

18. The RC IGBT of claim 16, wherein in the RC IGBT region, the body regions in the first type mesas exhibit a respective lateral dopant profile according to which the dopant concentration peaks in a lateral center region of the respective first type mesa.

19. The RC IGBT of claim 13, further comprising:
a barrier region of the first conductivity type that couples the trench-mesa-pattern in the IGBT-only region to the drift region,
wherein a dopant concentration of the barrier region is greater than a dopant concentration of the drift region.

20. The RC IGBT of claim 1, wherein:
a first channel-width-to-area-ratio is defined by a total channel width in the IGBT-only region divided by a total lateral area of IGBT-only region;
a second channel-width-to-area-ratio is defined by a total channel width in the RC IGBT region divided by a total lateral area of RC IGBT region; and
the second channel-width-to-area-ratio amounts to at least 120% of the first channel-width-to-area-ratio.

21. A method of operating a half bridge circuit comprising a first RC IGBT according to claim 1 and a second RC IGBT according to claim 1, the method comprising:
controlling the first RC IGBT based on the first control signal and the second control signal of the first RC IGBT; and
controlling the second RC IGBT based on the first control signal and the second control signal of the second RC IGBT.
